(19) United States
(12) Patent Application Publication
(10) Pub. No.: US 2025/0311129 A1
(43) Pub. Date: Oct. 2, 2025

(54) Transport Box for Ion Trap Module

(71) Applicant: Infineon Technologies Austria AG, Villach (AT)

(72) Inventors: Simon Matthias Schey, Villach (AT); Clemens Rössler, Villach (AT); Slike Katharina Auchter, Villach (AT); Yves Colombe, Villach (AT); Klemens Karl Heinrich Schüppert, Goritschach (AT); Christian Flasch, Mondsee (AT)

(21) Appl. No.: 19/089,195

(22) Filed: Mar. 25, 2025

(30) Foreign Application Priority Data
Mar. 26, 2024 (DE) 102024202859.2

(51) Int. Cl. H05K 5/06; B01D 53/04; B01D 53/26; B01D 53/28; B08B 5/00; B08B 7/00; B08B 7/04; G21K 1/00; H05K 5/00; H05K 5/04

(52) U.S. Cl. CPC H05K 5/06; B01D 53/0446; B01D 53/261; B01D 53/28; B08B 5/00; B08B 7/0057; B08B 7/04; G21K 1/00; H05K 5/0047; H05K 5/04; B01D 2253/102; B01D 2253/106; B01D 2253/108; B01D 2257/104; B01D 2257/708; B01D 2257/80

(57) ABSTRACT

A transport box for an ion trap module includes a base including a mounting surface configured to mount the ion trap module and a lid configured to be attached to the base to form a hermetically sealed first volume in the transport box. The ion trap module is enclosable in the first volume. The base and the lid are manufactured from at least one of a metal, a metal alloy, and a low-outgassing polymer.

### TECHNICAL FIELD

The present disclosure relates to a transport box for an ion trap module and a method for storing an ion trap module in a transport box.

### BACKGROUND

Ion trap modules may include a plurality of electrodes for trapping ions in a trapping zone above the electrodes. It may be problematic to passivate these trap electrodes in a suitable way like electrodes in conventional semiconductor devices. Ions trapped in the trapping zone by electric fields may easily be disturbed by any kind of stray charges or contaminations on surfaces of the electrodes. It may thus be desirable to provide an improved protection of the ion trap modules and in particular of their trap electrodes. In particular, it may be desirable to avoid or at least minimize contamination and oxidation of the trap electrodes.

### SUMMARY

An aspect of the present disclosure relates to a transport box for an ion trap module. The transport box comprises a base comprising a mounting surface for mounting the ion trap module and a lid configured to be attached to the base to form a hermetically sealed first volume in the transport box. The ion trap module is enclosable in the first volume. The base and the lid are both manufactured from at least one of a metal, a metal alloy, and a low-outgassing polymer.

A further aspect of the present disclosure relates to a method for storing an ion trap module in a transport box. The method comprises an act of mounting the ion trap module on a mounting surface of a base. The method further comprises an act of attaching a lid to the base to form a hermetically sealed first volume in the transport box enclosing the ion trap module. The method further comprises an act of flushing the hermetically sealed first volume with a gas for providing a selected gas atmosphere in the first volume, wherein the gas is fed into the first volume via a gas inlet valve of the transport box and exits the first volume via a gas outlet valve of the transport box.

### BRIEF DESCRIPTION OF THE DRAWINGS

Devices and methods in accordance with the disclosure are described in more detail below based on the drawings. Similar reference numerals may designate corresponding similar parts. The technical features of the various illustrated examples may be combined unless they exclude each other and/or can be selectively omitted if not described to be necessarily required.

FIGS. 1A to 1C illustrate a transport box 100 for an ion trap module in accordance with the disclosure. FIG. 1A illustrates a perspective view of the transport box 100, FIG. 1B illustrates a cross-sectional side view of the transport box 100, and FIG. 1C illustrates the transport box 100 in an opened position.

FIG. 2 illustrates a flowchart of a method for storing an ion trap module in a transport box in accordance with the disclosure.

### DETAILED DESCRIPTION

In the following, transport boxes for ion trap modules are described. An ion trap module may be a micro-fabricated device for controlling trapped ions. In some examples, the ion trap module may include a printed circuit board (PCB) and an ion trap chip arranged thereon. The ion trap chip may include a substrate and a structured electrode layer arranged over the substrate. The structured electrode layer may form a plurality of electrodes configured to trap ions in a trapping zone above the structured electrode layer. The locations of the trapped ions may be controlled by electrical voltages applied to the electrodes of the structured electrode layer.

In general, ion trap modules may be sensitive with regard to various influences. For example, ions trapped in the trapping zone by electric fields may easily be disturbed by any kind of stray charges or contaminations on the electrode surfaces. Accordingly, adsorption on the electrode surfaces and any kind of oxidation of the electrode surfaces is to be avoided or at least minimized. However, it may be problematic to provide a suitable passivation of the electrode surfaces. The transport boxes described herein are configured to provide a suitable protection of ion trap modules and their structured electrode layers. This enables proper storage and transport of the ion trap modules.

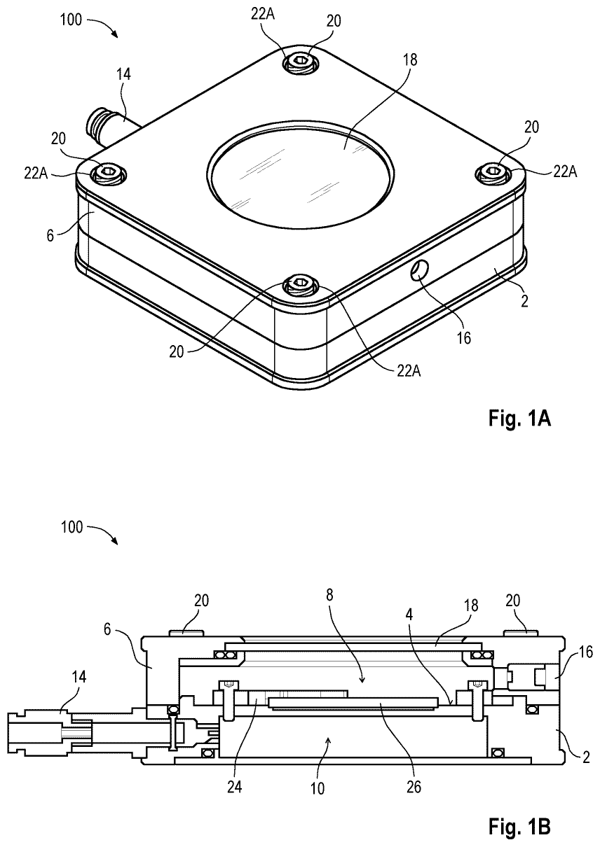

Referring now to FIGS. 1A to 1C, a transport box 100 for an ion trap module in accordance with the disclosure is illustrated from different perspectives. The transport box 100 may include a base 2 including a mounting surface 4 for mounting the ion trap module. The transport box 100 may further include a lid 6 configured to be attached to the base 2 to form a hermetically sealed first volume 8 in the transport box 100. The ion trap module is enclosable in the first volume 8. That is, the ion trap module may be enclosed in the first volume 8. The base 2 and the lid 6 both may be manufactured from (i.e., comprise) at least one of a metal, a metal alloy, and a low-outgassing polymer.

In some examples, the base 2 and the lid 6 may be manufactured from a metal and/or a metal alloy. More particularly, the base 2 and the lid 6 both may be manufactured from at least one of stainless steel, aluminum, titanium, and alloys thereof. For the case of the base 2 being manufactured from a metal or a metal alloy, an ion trap module arranged in the transport box 100 may be electrically grounded to the base 2. The transport box 100 may thus provide an electrostatic discharge-(ESD)-safe container for the ion trap module, thereby preventing electrical short circuits on the ion trap module that may otherwise occur.

In further examples, the base 2 and the lid 6 may be manufactured from a low-outgassing polymer. The low-outgassing polymer may have a total mass loss (TML) value smaller than 1.0% and a collected volatile condensable material (CVCM) value smaller than 0.1%. The terms “low-outgassing” and “low-outgassing polymer” have recognized meanings in the art and are commonly used by e.g. polymer manufacturers and materials science publications. In some examples, the term “low-outgassing” may be specified by the (in particular latest) “Standard Test Method for TML and CVCM from Outgassing in a Vacuum Environment” of the American Society for Testing and Materials (ASTM). This test method evaluates, under carefully controlled conditions, the changes in the mass of a test specimen on exposure under vacuum to a temperature of 125° C. and the mass of those products that leave the specimen and condense on a collector at a temperature of 25° C. The mass loss of the specimen may be determined from the weights before and after the 125° C. exposure, and the percentage loss may be calculated to provide the TML. In a similar manner, the difference between the weight of a clean collector and of the collector having condensed materials will provide the mass of condensables. This mass of condensables may be calculated as a percentage of the starting mass of the sample, and stated as CVCM.

The transport box 100 may include a sealing material configured to hermetically connect (or hermetically seal) the base 2 and the lid 6 to form the first volume 8. In some examples, the sealing material may be manufactured from at least one of a metal, a metal alloy, and a low-outgassing polymer. In particular, the sealing material may be manufactured from at least one of a fluorocarbon-based elastomer, Viton® (a fluoropolymer elastomer and synthetic rubber compound), silicone, copper, and indium. In some examples, the sealing material may include at least one gasket. In one specific example, the sealing material may include at least one Viton® gasket. In a further specific example, the sealing material may include at least one copper gasket and/or indium gasket which may particularly be suitable for ultra-high vacuum (UHV) applications. Due to providing the hermetic connection between the base 2 and the lid 6, the sealing material may prevent an uncontrolled gas exchange with the environment. In this way, a generation of a hermetically sealed volume inside the transport box 100 may be supported.

The transport box 100 may include a second volume 10 for storing an absorber material configured to absorb one or more gaseous substances. For example, the one or more gaseous substances may include one or more outgassed substances or one or more other substances. The one or more outgassed substances may be present in the transport box 100 due to outgassing of some of the materials which form part of transport box 100. For example the one or more outgassed substances may include one or more organic compounds (such as volatile organic compounds). The one or more other substances may have entered the transport box 100 when the transport box 100 was opened outside of vacuum (such as water or oxygen), for example. The first volume 8 and the second volume 10 may be connected for gas exchange. In the illustrated example, the second volume 10 may be formed in the base 2 and beneath the mounting surface 4. The mounting surface 4 may include at least one opening 12 configured to provide gas exchange between the first volume 8 and the second volume 10. The openings 12 may allow the atmosphere of the first volume 8 and the second volume 10 to exchange, but may also prevent the absorber material in the second volume 10 from damaging the ion trap module in the separate first volume 8. The absorber material arranged in the second volume 10 may include at least one of a molecular sieve, activated carbon, zeolite, and silica gel. The absorber material may be configured to remove gaseous substances from the atmosphere in the transport box 100. This may minimize the effects of volatile organic compounds or moisture, which can lead to contamination or oxidation of the structured electrode layer of the ion trap module.

The transport box 100 may include at least one gas inlet valve 14 and at least one gas outlet valve 16 configured for flushing the first volume 8 with a gas. In particular, the valves 14 and 16 may correspond to valves with fixed differential pressure. In the illustrated example, the gas inlet valve 14 may be connected to the base 2 and configured to provide a gas flow from the environment to the second volume 10. In addition, the gas outlet valve 16 may be connected to the lid 6 and configured to provide a gas flow from the first volume 8 to the environment. The valves 14 and 16 may thus be configured to provide a controlled gas exchange with the environment.

In a first scenario, the hermetically sealed first volume 8 may be flushed with a selected gas for providing a selected gas atmosphere in the first volume 8. For this purpose, the gas inlet valve 14 may be connected to a source of the selected gas and the gas may be fed into the second volume 10 via the gas inlet valve 14. The gas may enter the first volume 8 via the openings 12 and may then exit the first volume 8 via the gas outlet valve 16. In this way, a constant gas flow through the transport box 100 may be established, wherein the volumes 8 and 10 of the transport box 100 may be flushed and a previous gas atmosphere may be replaced by a gas atmosphere of the selected gas. In one example, the selected gas may include or may correspond to an inert gas such that an inert gas atmosphere inside the transport box 100 may be provided. In one example, the selected gas may include or may be nitrogen gas and the selected gas atmosphere may be a nitrogen atmosphere. In another example, the selected gas may include or may be argon gas and the selected gas atmosphere may be an argon atmosphere. Due to the inert gas atmosphere contamination and/or oxidation of the structured electrode layer of the ion trap module may be avoided or at least minimized. In a second scenario, a vacuum may be generated in the volumes 8 and 10 of the transport box 100. The transport box 100 may then be vacuum-sealed such that a storage or transport of the ion trap module under vacuum may be possible. In such case, the gas inlet valve 14 and the gas outlet valve 16 may be vacuum sealing valves.

The transport box 100 may include at least one transparent glass window 18. In the illustrated example, a single transparent glass window 18 having a circular shape may be arranged in the lid 6. It is to be understood that the glass window 18 may have a different shape in further examples. The glass window 18 may be configured to provide a view on the ion trap module arranged in the transport box 100 from outside of the transport box 100. In this way, an identification of the ion trap module in the transport box 100 may be possible during storage and/or transportation. In addition, damage to the ion trap module that may emerge during storage and/or transportation can be detected through the glass window 18 without having to unpack the ion trap module.

The transport box 100 may include at least one connection element configured to mechanically connect the base 2 and the lid 6. In the illustrated example, the at least one connection element may include an exemplary number of four screws 20 for fixing the lid 6 to the base 2. The screws 20 may be inserted into openings 22A extending through the lid 6 and into openings 22B on the upper surface of the base 2 and may be tightened, thereby firmly connecting the base 2 and the lid 6. In further examples, the transport box 100 may be opened and/or closed based on a different mechanism. In one case, the transport box 100 may include one or multiple flexible hinges that can be attached to the base 2 and the lid 6 so that the transport box 100 can be flipped open. In yet another case, the transport box 100 may include one or multiple clamps that may fix the lid 6 to the base 2.

Referring now to FIG. 1C in particular, the interior of the transport box 100 is illustrated, wherein the lid 6 is not shown. The transport box 100 may include a plurality of clamps 24 configured to fix the ion trap module to the base 2. For example, the ion trap module may include at least one PCB and at least one ion trap chip arranged on the at least one PCB. In one example, a single ion trap chip may be mounted on the PCB. In further examples, more than only one ion trap chip may be arranged on the PCB. In FIG. 1C, for the sake of simplicity, only a PCB 26 of the ion trap module is shown while a possible ion trap chip arranged thereon is not illustrated. In the illustrated example, the mounting surface 4 may include an optional recess 28, wherein the ion trap module (or more particular the PCB 26) may be arranged in the recess 28.

The clamps 24 may be manufactured from a low-outgassing polymer. In particular, the clamps 24 may be manufactured from at least one of POM-C and PTFE. The clamps 24 may be connected to the mounting surface 4 of the base 2 and may be configured to fix the ion trap module (or more particular the PCB 26) to the mounting surface 4. For example, each of the clamps 24 may be pivotable parallel to the mounting surface 4. In the illustrated case, one end of each clamp 24 may be fixed to the mounting surface 4 (e.g. by a screw) such that the respective clamp 24 may be rotatable around its fixed end. The clamps 24 may be configured to secure the ion trap module in the transport box 100 such that damage to the ion trap module during storage, transportation, installation or removal may be prevented.

In the illustrated example, the clamps 24 and their fixation to the mounting surface 4 may be designed for a specific size of the PCB 26. In order to be able to fix PCBs of other sizes to the mounting surface 4, an adapter plate may be arranged on the mounting surface 4. The clamps 24 may then be connected to a surface of this adapter plate at positions adapted to the size of the respective PCB 26. Here, the clamps 24 may be pivotable parallel to the mounting surface 4 and configured to fix the respective PCB 26 to the adapter plate instead of to the mounting surface 4. The adapter plate may include multiple positions for the clamps 24 such that PCBs of different sizes may be fixed to the adapter plate. Alternatively, different adapter plates may be used for different PCB sizes.

In the illustrated example of FIGS. 1A to 1C, the transport box 100 may include a single PCB 26. However, in further examples, the transport box 100 may include more than only one PCB 26. In one scenario, the multiple PCBs 26 may be arranged laterally offset to each other on the mounting surface 4 of the base 2. Each one of the multiple PCBs 26 may be fixed by clamps 24 as previously described. In an alternative scenario, the number of PCBs 26 stored in the transport box 100 may be increased by stacking at least some of the PCBs 26.

In summary, a transport box in accordance with the disclosure may repeatedly provide a controlled gas atmosphere for an ion trap module stored in the transport box. In particular, the gas atmosphere may be inert and free of undesired substances, such as water, oxygen or volatile organic compounds. The hermetically sealed transport box may be made (in particular entirely) of non-outgassing and/or low-outgassing materials and may be filled with the inert gas atmosphere which may be maintained by the absorber material. As a result, contamination and oxidation of the ion trap module (more particular of its electrodes) may be prevented or at least minimized. The performance of the ion trap module may therefore remain unaffected. In addition, a repeated cleaning of the ion trap module (more particular of its electrodes) may become unnecessary. The clamps 24 may be provided for securing the ion trap module inside the transport box. The transparent glass window 18 may provide an identification of the ion trap module arranged inside the transport box.

It is to be noted that a transport box as described herein may particularly represent a hand-portable device that is not to be confused with a heavy stationary arrangement in which an ion trap module may be placed, such as a non-hand-portable vacuum chamber of e.g. an experimental setup. In particular, the transport box 100 may be exclusively configured for storing and transporting an ion trap module arranged therein. That is, the transport box 100 may not necessarily include additional electronic elements or additional electrical terminals that may be required for an actual operation of the ion trap module.

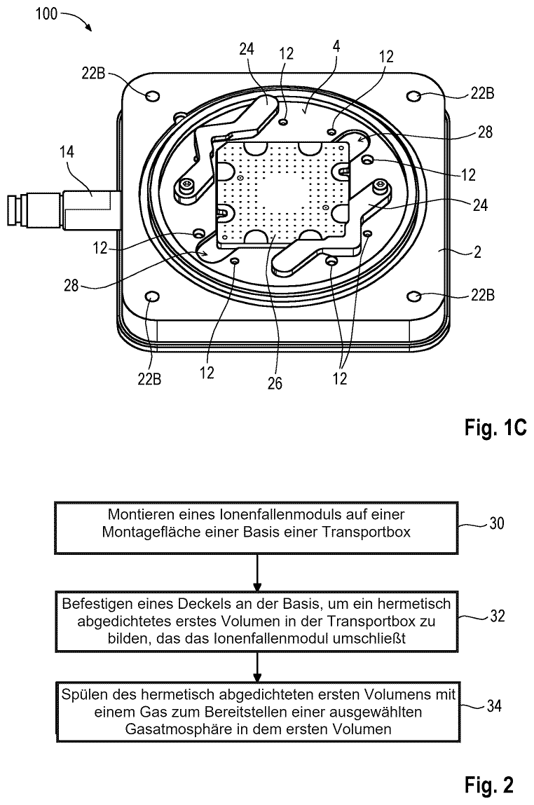

FIG. 2 illustrates a method for storing an ion trap module in a transport box such as the transport box 100 of FIGS. 1A to 1C. The method may be extended by any of the aspects previously described. In particular, the method may be carried out for providing a selected gas atmosphere inside the transport box. Note that more details for providing a selected gas atmosphere in a transport box have been discussed in connection with FIGS. 1A to 1C.

At 30, the ion trap module may be mounted on a mounting surface of a base. At 32, a lid may be attached to the base to form a hermetically sealed first volume in the transport box enclosing the ion trap module. At 34, the hermetically sealed first volume may be flushed with a gas for providing a selected gas atmosphere in the first volume. The gas may be fed into the first volume via a gas inlet valve of the transport box and may exit the first volume via a gas outlet valve of the transport box. In particular, the gas may include nitrogen gas and the selected gas atmosphere may be a nitrogen atmosphere.

In one embodiment, the transparent glass window 18 may comprise or may be an ultra-violet (UV) transparent glass window. For example, glass window 18 may be transparent for light wavelengths that are less or equal to 255 nm. This may enable cleaning of the ion trap module by a UV-ozone cleaning process (e.g., to clean organic contaminants from the ion trap module) inside the transport box 100.

The UV-ozone cleaning process may comprise feeding oxygen into the transport box 100. In one example, this can be done by closing the lid 8 such that air is enclosed inside the transport box. In another example, a gas that comprises oxygen can be inserted into the transport box 100 via gas inlet valve 14. The UV-cleaning process may further comprise irradiating the oxygen within the transport box with an UV light. For example, a UV light source may be placed outside the transport box 100 and may emit UV light through UV transparent glass window 18. In yet another example (not shown), the UV light source may be placed inside the transport box 100. In the later case, the UV transparent glass may not be needed.

In the following, transport boxes for ion trap modules and methods for storing an ion trap module in a transport box in accordance with the disclosure are described by means of examples.

Example 1 is a transport box for an ion trap module, comprising: a base comprising a mounting surface for mounting the ion trap module; and a lid configured to be attached to the base to form a hermetically sealed first volume in the transport box, wherein the ion trap module is enclosable in the first volume, wherein the base and the lid are both manufactured from at least one of a metal, a metal alloy, and a low-outgassing polymer.

Example 2 is a transport box according to Example 1, wherein the base and the lid are both manufactured from at least one of stainless steel, aluminum, and titanium.

Example 3 is a transport box according to Example 1 or 2, wherein the low-outgassing polymer has a TML value smaller than 1.0% and a CVCM value smaller than 0.1%.

Example 4 is a transport box according to any of the preceding Examples, further comprising: a sealing material configured to hermetically connect the base and the lid to form the first volume.

Example 5 is a transport box according to Example 4, wherein the sealing material is manufactured from at least one of a metal, a metal alloy, and a low-outgassing polymer.

Example 6 is a transport box according to Example 4 or 5, wherein the sealing material is manufactured from at least one of a fluorocarbon-based elastomer, Viton®, silicone, copper, and indium.

Example 7 is a transport box according to any of the preceding Examples, further comprising: a second volume in the transport box for storing an absorber material configured to absorb one or more gaseous substances, wherein the first volume and the second volume are connected for gas exchange.

Example 8 is a transport box according to Example 7, wherein: the second volume is formed in the base and beneath the mounting surface, and the mounting surface comprises at least one opening configured to provide gas exchange between the first volume and the second volume.

Example 9 is a transport box according to Example 7 or 8, wherein: the one or more gaseous substance comprises at least one of water, oxygen, and volatile organic compounds, and/or the absorber material comprises at least one of a molecular sieve, activated carbon, zeolite, and silica gel.

Example 10 is a transport box according to any of the preceding Examples, further comprising: a gas inlet valve and a gas outlet valve configured for flushing the first volume with a gas.

Example 11 is a transport box according to Example 10, wherein: the gas inlet valve is connected to the base and configured to provide a gas flow from the environment to the second volume, and the gas outlet valve is connected to the lid and configured to provide a gas flow from the first volume to the environment.

Example 12 is a transport box according to any of the preceding Examples, further comprising: a plurality of clamps configured to fix the ion trap module to the base.

Example 13 is a transport box according to Example 12, wherein: the ion trap module comprises at least one PCB and at least one ion trap chip arranged on the at least one PCB, and the clamps are connected to the mounting surface and configured to fix the at least one PCB to the mounting surface.

Example 14 is a transport box according to Example 12, wherein: the ion trap module comprises at least one PCB and at least one ion trap chip arranged on the at least one PCB, and the clamps are connected to an adapter plate arranged on the mounting surface and configured to fix the at least one PCB to the adapter plate.

Example 15 is a transport box according to any of Examples 12 to 14, wherein the clamps are manufactured from POM-C and/or PTFE.

Example 16 is a transport box according to any of Examples 12 to 15, wherein the clamps are pivotable parallel to the mounting surface.

Example 17 is a transport box according to any of the preceding Examples, further comprising: a transparent glass window arranged in the lid and configured to provide a view on the ion trap module from outside of the transport box.

Example 18 is a transport box according to any of the preceding Examples, wherein: the base is manufactured from a metal or a metal alloy, and the ion trap module is electrically grounded to the base.

Example 19 is a transport box according to any of the preceding Examples, wherein the mounting surface comprises a recess and the ion trap module is arranged in the recess.

Example 20 is a method for storing an ion trap module in a transport box, the method comprising: mounting the ion trap module on a mounting surface of a base, attaching a lid to the base to form a hermetically sealed first volume in the transport box enclosing the ion trap module; and flushing the hermetically sealed first volume with a gas for providing a selected gas atmosphere in the first volume, wherein the gas is fed into the first volume via a gas inlet valve of the transport box and exits the first volume via a gas outlet valve of the transport box.

Example 21 is a method according to Example 20, wherein the gas comprises nitrogen gas and the selected gas atmosphere is a nitrogen atmosphere.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The expression “and/or” should be interpreted to cover all possible conjunctive and disjunctive combinations, unless expressly noted otherwise. For example, the expression “A and/or B” should be interpreted to mean A but not B, B but not A, or both A and B. The expression “at least one of” should be interpreted in the same manner as “and/or”, unless expressly noted otherwise. For example, the expression “at least one of A and B” should be interpreted to mean A but not B, B but not A, or both A and B.

The features of the various examples described herein may be combined with each other unless specifically noted otherwise. Although specific examples have been illustrated and described herein, it will be appreciated by those of ordinary skill in the art that a variety of alternate and/or equivalent implementations may be substituted for the specific examples shown and described without departing from the scope of the present invention. This application is intended to cover any adaptations or variations of the specific examples discussed herein. Therefore, it is intended that this invention be limited only by the claims and the equivalents thereof.

What is claimed is:

1. A transport box for an ion trap module, the transport box comprising:
a base comprising a mounting surface configured to mount the ion trap module; and
a lid configured to be attached to the base to form a hermetically sealed first volume in the transport box, such that the ion trap module is enclosable in the first volume,
wherein the base and the lid both comprise at least one of a metal, a metal alloy, and a low-outgassing polymer.

2. The transport box of claim 1, wherein the base and the lid both comprise at least one of stainless steel, aluminum, and titanium.

3. The transport box of claim 1, wherein the low-outgassing polymer has a total mass loss (TML) value smaller than 1.0% and a collected volatile condensable material (CVCM) value smaller than 0.1%.

4. The transport box of claim 1, further comprising:
a sealing material configured to hermetically connect the base and the lid to form the first volume.

5. The transport box of claim 4, wherein the sealing material comprises at least one of a metal, a metal alloy, and a low-outgassing polymer.

6. The transport box of claim 4, wherein the sealing material comprises at least one of a fluorocarbon-based elastomer, a fluoropolymer elastomer and synthetic rubber compound, silicone, copper, and indium.

7. The transport box of claim 1, further comprising:
a second volume in the transport box configured to store an absorber material configured to absorb one or more gaseous substances,
wherein the first volume and the second volume are connected for gas exchange.

8. The transport box of claim 7, wherein:
the second volume is formed in the base beneath the mounting surface; and
the mounting surface comprises at least one opening configured to provide the gas exchange between the first volume and the second volume.

9. The transport box of claim 7, wherein:
the one or more gaseous substances comprises at least one of water, oxygen, and volatile organic compounds; and/or
the absorber material comprises at least one of a molecular sieve, activated carbon, zeolite, and silica gel.

10. The transport box of claim 1, further comprising:
a gas inlet valve and a gas outlet valve configured to flush the first volume with a gas.

11. The transport box of claim 10, wherein:
the gas inlet valve is connected to the base and configured to provide a gas flow from the environment to the second volume; and
the gas outlet valve is connected to the lid and configured to provide a gas flow from the first volume to the environment.

12. The transport box of claim 1, further comprising:
a plurality of clamps configured to fix the ion trap module to the base.

13. The transport box of claim 12, wherein:
the ion trap module comprises at least one printed circuit board (PCB) and at least one ion trap chip arranged on the at least one PCB; and
the clamps are connected to the mounting surface and configured to fix the at least one PCB to the mounting surface.

14. The transport box of claim 12, wherein:
the ion trap module comprises at least one printed circuit board (PCB) and at least one ion trap chip arranged on the at least one PCB; and
the clamps are connected to an adapter plate arranged on the mounting surface and configured to fix the at least one PCB to the adapter plate.

15. The transport box of claim 12, wherein the clamps comprise POM-C and/or PTFE.

16. The transport box of claim 12, wherein the clamps are pivotable parallel to the mounting surface.

17. The transport box of claim 1, further comprising:
a transparent glass window arranged in the lid.

18. The transport box of claim 17,
wherein the glass window comprises a UV transparent glass.

19. The transport box of claim 1,
further comprising a UV lamp arranged inside the transport box.

20. A method for storing an ion trap module in a transport box, the method comprising:
mounting the ion trap module on a mounting surface of a base;
attaching a lid to the base to form a hermetically sealed first volume in the transport box that encloses the ion trap module; and
flushing the hermetically sealed first volume with a gas to provide a selected gas atmosphere in the first volume,
wherein the gas is fed into the first volume via a gas inlet valve of the transport box and exits the first volume via a gas outlet valve of the transport box.
